(19) United States
(12) Patent Application Publication
(10) Pub. No.: US 2024/0391517 A1
(43) Pub. Date: Nov. 28, 2024

(54) Control Device, in particular Steering Control Device

(71) Applicant: Robert Bosch GmbH, Stuttgart (DE)

(72) Inventors: Stefan Ehlert, Goeppingen (DE); Daniel Froelich, Schwaebisch Gmuend (DE); Steffen Kuhn, Urbach (DE)

(21) Appl. No.: 18/668,184

(22) Filed: May 19, 2024

(30) Foreign Application Priority Data
May 25, 2023 (DE) 10 2023 204 901.5

(51) Int. Cl. B62D 5/04

(52) U.S. Cl. CPC B62D 5/0406

(57) ABSTRACT

A control device, in particular a steering control device, includes (i) an electronics unit that has at least two separate and mutually independent subsystems for controlling an electric motor and/or for detecting at least one operating variable of the electric motor, and (ii) a printed circuit board on which the electronics unit is arranged. The printed circuit board has at least one electrically non-conductive separating section which electrically separates the two subsystems from one another.

This application claims priority under 35 U.S.C. § 119 to patent application no. DE 10 2023 204 901.5, filed on May 25, 2023 in Germany, the disclosure of which is incorporated herein by reference in its entirety.

The disclosure relates to a control device. In addition, the disclosure relates to an actuator assembly having such a control device, as well as a steering system having such an actuator assembly.

### BACKGROUND

Steering systems comprising steering actuators with an electric motor and a control device for controlling the drive of the electric motor are known from the prior art. The control device generally comprises an electronics housing adjacent to the electric motor and an electronics unit arranged in the electronics housing for controlling the electric motor and/or for detecting at least one operating variable of the electric motor. By way of example, reference is made in this context to DE 11 2019 005 409 T5, which discloses a corresponding actuator assembly.

Based on this, the task of the disclosure is in particular to provide a control device with improved properties with regard to an insulating effect. The object is achieved by the features of set forth below, while advantageous configurations and further developments of the disclosure can be found in the description herein.

### SUMMARY

The disclosure is based on a control device, in particular a steering control device, having an electronics unit which comprises at least two separate and mutually independent, in particular electrical and/or electronic, subsystems for controlling an electric motor and/or for detecting at least one operating variable of the electric motor, and having a printed circuit board on which the electronics unit is arranged.

It is proposed that the printed circuit board has at least one electrically non-conductive separating section which electrically separates the two subsystems from each other. This configuration can achieve an improved insulation effect in particular. In particular, this can prevent an electrically conductive particle from causing a failure of both subsystems. In addition, a control device with an advantageous structure can be provided. In addition, efficiency, in particular installation space efficiency, component efficiency, performance efficiency and/or cost efficiency, can be advantageously improved.

In this context, a “control device” is to be understood as at least one part, in particular a sub-assembly, of an actuator assembly, which is provided in at least one operating state for controlling the operation of at least one electric motor of the actuator assembly. The electric motor can, for example, be designed as a brushless motor and advantageously as an asynchronous motor or as a permanently excited synchronous motor. In addition, the electric motor can advantageously comprise a motor housing, in particular designed as a mounting housing, and/or at least one end shield. Furthermore, the control device preferably comprises an electronics housing, in particular adjacent to the electric motor, advantageously the end shield, and preferably directly coupled to the electric motor, in which at least the electronics unit and the printed circuit board are arranged. Furthermore, the subsystems of the electronics unit are preferably redundant subsystems, each of which is provided for controlling the electric motor and/or for detecting the at least one operating variable of the electric motor. In the present case, each of the subsystems can comprise control electronics, in particular in the form of control logic and/or power electronics, for controlling the electric motor and/or detection electronics for detecting at least one operating variable, such as a rotor position and/or a temperature, of the electric motor. In addition, the printed circuit board comprises a carrier substrate, in particular in the form of a base body, and preferably at least one conductor track arranged on the carrier substrate. The separating section can be designed as a separating gap, for example. Preferably, however, the separating section is designed as a physical and/or physical barrier, in particular a separating barrier and/or insulation barrier, and in particular is different from an air gap. The dimensions, in particular a width and/or a height, of the separating section are selected in a particularly advantageous way so that all electrically conductive objects, in particular particles, that occur and/or arise during production cannot establish an unwanted electrical connection between the subsystems. In this case, the separating section can advantageously have a width and/or height of at least 0.5 mm, in particular at least 2 mm, and/or of at most 10 mm, in particular at most 5 mm. “Provided” is to be understood in particular as specifically designed and/or equipped. In particular, the phrase “an object being provided for a specific function” is intended to mean that the object fulfills and/or performs this specific function in at least one application—and/or operating state.

It is also advantageously proposed that the separating section extends from a first side edge of the printed circuit board to a second side edge of the printed circuit board opposite the first side edge. In particular, the separating section in this case separates a top surface of the printed circuit board into two printed circuit board sections, in particular a left and a right printed circuit board section or an upper and a lower printed circuit board section, wherein one subsystem is arranged in a first printed circuit board section of the printed circuit board sections and the other subsystem is arranged in a second printed circuit board section of the printed circuit board sections. This enables particularly effective separation of the subsystems.

The separating section could, for example, have a curved course and/or a curved course. Preferably, however, it is proposed that the separating section has a straight course over its entire length and in particular is free of changes in direction, for example in the form of kinks and/or curves. In particular, this can achieve an advantageously symmetrical arrangement of the subsystems and/or minimize manufacturing costs.

In addition, it is proposed that the separating section is formed in one piece with the printed circuit board, i.e. connected at least with a material bond. In particular, the separating section is inseparably connected to the printed circuit board in this case. In particular, this can improve efficiency, especially component efficiency, manufacturing efficiency and/or cost efficiency.

According to one aspect, the separating section is applied directly to the top surface of the printed circuit board as an insulating layer. In this case, the carrier substrate of the printed circuit board and the insulating layer can advantageously consist at least partially of different materials. In particular, this allows advantageous flexibility and/or variability to be achieved.

Alternatively, it is proposed that the separating section is formed directly by the printed circuit board, in particular the carrier substrate, and is designed as a raised and/or recessed section, in particular of the carrier substrate. In this case, the separating section therefore corresponds to a physical barrier. In principle, the separating section in this case could also have several elevations and/or depressions, in particular in a row and/or offset in parallel. In particular, this can reduce the amount of material and/or manufacturing steps required.

It is further proposed that the control device comprises a communication unit which provides a communication connection between the subsystems. Preferably, the communication unit can comprise at least one CAN transceiver and/or at least one overvoltage-protected decoupling element, so that an intact sub-machine remains protected even in the event of a defect and a resulting overvoltage in the communication connection. This principle therefore rules out the possibility of a random hardware error and/or electrically conductive particles causing a failure of both subsystems. This makes it possible to realize advantageous secure communication between the subsystems.

The control device, the actuator assembly and the steering system are not intended to be limited to the application and embodiment described above. In particular, the control device, the actuator assembly and the steering system can have a number of individual elements, components and units other than a number specified herein in order to fulfill a function described herein.

### BRIEF DESCRIPTION OF THE DRAWINGS

Further advantages follow from the description of the drawings hereinafter. The drawings show an embodiment example of the disclosure.

The drawings show:

FIG. 1 a part of an exemplary steering system with an actuator assembly designed as a steering actuator comprising an electric motor and a control device in a perspective view,

FIG. 2 a section of the actuator assembly in a schematic representation and

FIG. 3 at least a part of the control device in a plan view.

### DETAILED DESCRIPTION

The following embodiment example relates, by way of example, to a steering system. In principle, however, the disclosure is not limited to use in a steering system and could, for example, also be used in other areas of a vehicle, such as a window regulator system and/or a drive system, and/or in other electronic systems, for example in the area of household appliances and/or machine tools.

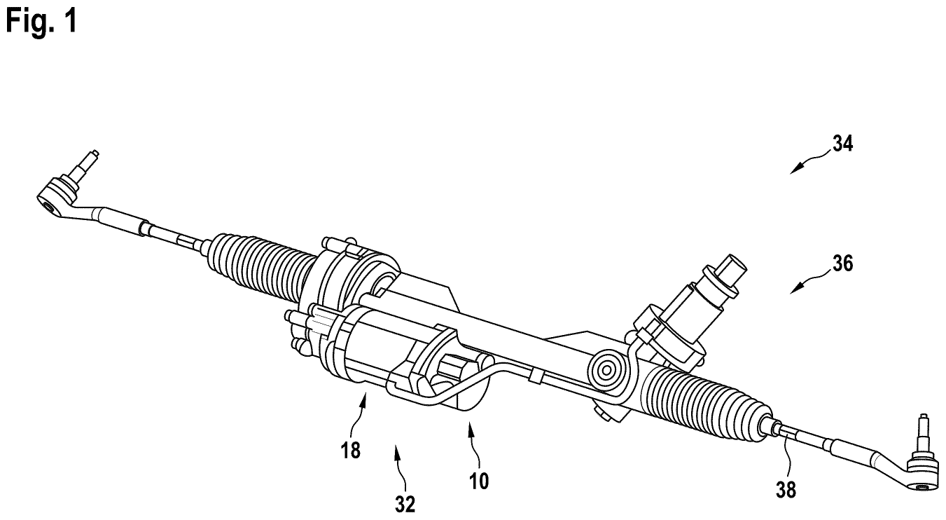

FIG. 1 shows at least a portion of an exemplary steering system 34 in a perspective view. In the present case, the steering system 34 is configured as an electrically assisted steering system. The steering system 34 is configured by way of example as a conventional steering system and comprises an auxiliary electric steering in the form of a power steering. Furthermore, the steering system 34 is provided for use in a vehicle (not shown), in particular a motor vehicle. In an installed state, the steering system 34 has an operative connection with vehicle wheels (not shown) of the vehicle and is intended to influence a direction of travel of the vehicle. Alternatively, however, it is also conceivable to design a steering system as a steer-by-wire steering system.

The steering system 34 comprises a steering gear 36, exemplarily designed as a rack-and-pinion steering gear, which is intended to convert a steering input into a steering movement of the vehicle wheels. For this purpose, the steering gear 36 comprises at least one steering adjusting element 38, which in the present case is designed in particular as a toothed rack.

Furthermore, the steering system 34 comprises at least one actuator assembly 32. The actuator assembly 32 is designed as a steering actuator and has an operative connection with the steering adjusting element 38. The actuator assembly 32 is provided to provide steering torque. In the present case, the actuator assembly 32 is intended to provide a steering torque in the form of an assistance torque and/or servo torque and to apply it, in particular for steering assistance, to the steering gear 36. Alternatively, an actuator assembly could also be part of a steer-by-wire steering system. In this case, the actuator assembly could be particularly provided for use in a wheel steering angle adjuster and in particular to provide a steering torque for direct control of a direction of travel of a vehicle. In this case, the actuator assembly could also be provided for use in a control unit of the steer-by-wire steering system and for providing a feedback torque and/or resetting torque to a steering handle. Furthermore, as mentioned above, an actuator assembly could also be used independently of a steering system.

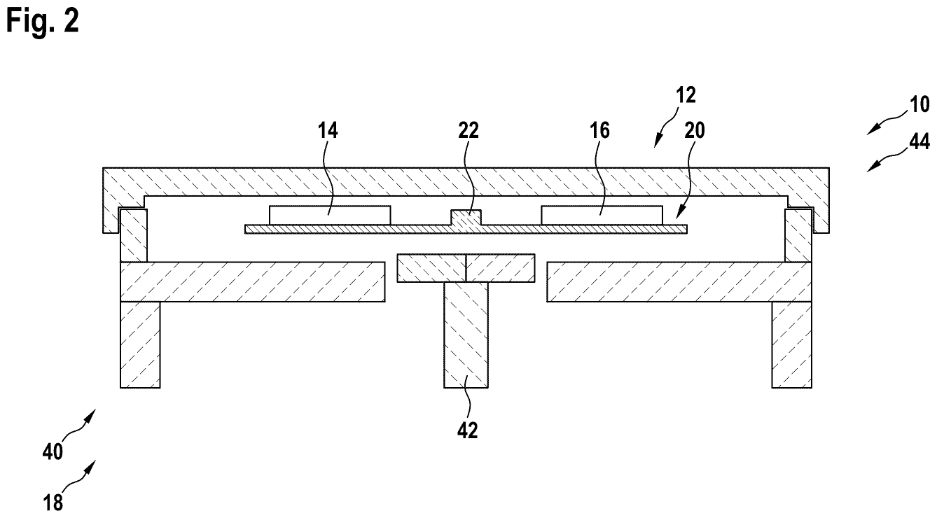

The actuator assembly 32 comprises an electric motor 18 known per se (see in particular FIG. 2). The electric motor 18 is designed as a permanently excited synchronous motor and is intended to generate the steering torque. The electric motor 18 comprises a motor housing 40, in particular designed as an outer housing, a stator (not shown) arranged in the motor housing 40, a rotor (not shown) arranged in the motor housing 40 and a motor shaft 42 arranged in the motor housing 40, which defines an axis of rotation of the electric motor 18.

Furthermore, the actuator assembly 32 has a control device 10 (see in particular FIG. 2). In this case, the control device 10 is designed as a steering control device. The control device 10 comprises an electronics housing 44. The electronics housing 44 is designed as an outer housing. The electronics housing 44 is designed as a mounting housing. The electronics housing 44 is directly adjacent to the electric motor 18 and is arranged axially to the motor shaft 42 of the electric motor 18. The electronics housing 44 is coupled to the electric motor 18, in particular the motor housing 40.

In addition, the control device 10 comprises an electronics unit 12. The electronics unit 12 is arranged in the electronics housing 44 and is provided for controlling the electric motor 18 and/or for detecting at least one operating variable of the electric motor 18. For this purpose, the electronics unit 12 comprises two separate and independent subsystems 14, 16, which are designed to be redundant to each other. In the present case, each of the subsystems 14, 16 comprises control electronics (not shown) for controlling the electric motor 18 and detection electronics (not shown) for detecting at least one operating variable of the electric motor 18. In principle, however, subsystems could also be designed differently from one another. In addition, at least one subsystem could be provided to control an electric motor or to detect at least one operating variable of the electric motor.

To accommodate the electronics unit 12, the control device 10 also comprises a printed circuit board 20. In the present embodiment example, the control device 10 comprises exactly one printed circuit board 20. Consequently, the entire electronics unit 12 and in particular the subsystems 14, 16 are arranged on the printed circuit board 20. The printed circuit board 20 is formed in one piece, i.e. all parts of the printed circuit board 20 are connected to each other with at least a material bond. The printed circuit board 20 is also rigid and/or dimensionally stable. Alternatively, a control device could also comprise several, in particular at least two or at least three, printed circuit boards. Furthermore, a printed circuit board could in principle also be designed as a flexible or rigid-flexible printed circuit board.

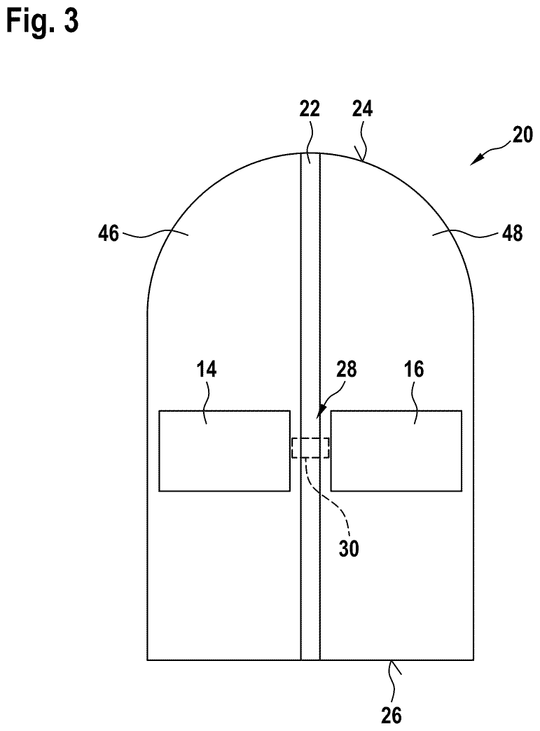

To improve an insulating effect, the printed circuit board 20 in the present case also comprises an electrically non-conductive separating section 22, which electrically separates the two subsystems 14, 16 from one another (cf. in particular also FIG. 3). The separating section 22 is designed as a physical and/or physical barrier and is different from a mere air gap. The separating section 22 is formed in one piece with the printed circuit board 20 and is therefore inseparably connected to the printed circuit board 20. In the present case, the separating section 22 can be applied directly to a top surface of the printed circuit board 20 as an insulating layer and/or formed directly by the printed circuit board 20 and designed as a raised or recessed area. Alternatively, a separating section could in principle also be a separating distance. Furthermore, the separating section 22 extends from a first side edge 24 of the printed circuit board 20 to a second side edge 26 of the printed circuit board 20 opposite the first side edge 24. In this way, the separating section 20 separates a top surface of the printed circuit board 20 into two separate printed circuit board sections 46, 48, in particular a left and a right printed circuit board section, wherein one subsystem 14 is arranged in a first printed circuit board section 46 of the printed circuit board sections 46, 48 and the other subsystem 16 is arranged in a second printed circuit board section 48 of the printed circuit board sections 46, 48. In addition, the separating section 22 has a straight course over its entire length and is therefore free of changes in direction, for example in the form of kinks and/or curves. In principle, however, a curved and/or winding course would also be conceivable. In addition, the dimensions, in particular a width and/or a height, of the separating section 22 are selected in such a way that no electrically conductive particles occurring and/or appearing in the control unit can establish an unwanted electrical connection between the subsystems 14, 16. In the present case, the width and/or height is between 0.5 mm and 10 mm.

In order to enable communication between the two subsystems 14, 16, the control device 10 also comprises a communication unit 28. The communication unit 28 is intended to provide a communication connection between the subsystems 14, 16. For this purpose, the communication unit 28 comprises at least one CAN transceiver 30. Alternatively, a communication unit could also comprise an overvoltage-protected decoupling element. This ensures that the intact sub-machine 14, 16 remains protected even in the event of a defect and a resulting overvoltage in the communication connection. This principle therefore rules out the possibility of a random hardware error and/or electrically conductive particles causing a failure of both subsystems 14, 16.

What is claimed is:

1. A control device, comprising:
an electronics unit which includes at least two separate and mutually independent subsystems configured to control an electric motor and/or detect at least one operating variable of the electric motor; and
a printed circuit board on which the electronics unit is arranged,
wherein the printed circuit board has at least one electrically non-conductive separating section which electrically separates the two subsystems from one another.

2. The control device according to claim 1, wherein the separating section extends from a first side edge of the printed circuit board to a second side edge of the printed circuit board opposite the first side edge.

3. The control device according to claim 1, wherein the separating section has a straight course over its entire length.

4. The control device according to claim 1, wherein the separating section is formed in one piece with the printed circuit board.

5. The control device according to claim 4, wherein the separating section is applied directly to the top surface of the printed circuit board as an insulating layer.

6. The control device according to claim 4, wherein the separating section is formed directly by the printed circuit board and is designed as a raised or recessed portion.

7. The control device according to claim 1, further comprising a communication unit configured to provide a communication connection between the subsystems.

8. The control device according to claim 7, wherein the communication unit includes at least one CAN transceiver and/or at least one overvoltage-protected decoupling element.

9. An actuator assembly, comprising:
at least one electric motor; and
at least one control device according to claim 1.

10. A steering system comprising at least one actuator assembly according to claim 9.

11. The control device of claim 1, wherein the control device is a steering control device.

12. The actuator assembly of claim 9, wherein the actuator assembly is a steering actuator.
